(19) United States
(12) Patent Application Publication
(10) Pub. No.: US 2025/0370350 A1
(43) Pub. Date: Dec. 4, 2025

(54) METHOD FOR MANUFACTURING SILICON BALANCE SPRINGS

(71) Applicant: Sercalo Microtechnology Ltd., Schaan (LI)

(72) Inventors: Cornel Marxer, Neuchâtel (CH); Gregoire Perregaux, Marin-Epagnier (CH)

(21) Appl. No.: 19/220,233

(22) Filed: May 28, 2025

(30) Foreign Application Priority Data
May 28, 2024 (CH) CH000563/2024
Nov. 19, 2024 (CH) CH001251/2024

(51) Int. Cl. G03F 7/00; G01L 5/00

(52) U.S. Cl. CPC G03F 7/70516; G01L 5/0057; G03F 7/70616; G03F 7/70658; G03F 7/706835; G03F 7/706851

(57) ABSTRACT

A method for manufacturing a batch of silicon balance springs from SOI (Silicon On Insulator) plates, designed to keep the value of the resilient torque of the balance springs within a given range. This method includes, in order, the following steps:
a—Photolithography and deep reactive ion etching (DRIE) of at least one SOI plate, on which there is at least one balance spring structure and a measurement structure,
b—Measuring a parameter of the measurement structure, the value of the measurement parameter being correlated to the value of the resilient torque of the balance spring in a manner known per se,
c—Precision adjusting the photolithography and DRIE parameters based on the value of said measurement parameter
d—Iterating steps a, b and c so as to continuously control the dissipation of the resilient torque of the balance springs.

### SCOPE OF THE INVENTION

The present invention relates to the field of horology. More specifically, it relates to a method for manufacturing a batch of silicon balance springs from SOI (Silicon On Insulator) plates, designed to keep the value of the resilient torque of the balance springs within a given range, with little dissipation within the batch.

The invention also relates to a batch of balance springs manufactured using such a method, and to an SOI plate comprising, after a photolithography step and a deep reactive ion etching (DRIE) step, at least one balance spring structure and a measurement structure, a parameter of which is measurable after partial HF etching, the value of the parameter being correlated to the value of the resilient torque of the balance spring in a manner known per se.

### BACKGROUND OF THE INVENTION

Several effects can cause a watch to run less accurately: temperature, oscillation amplitude and the Earth's magnetic field can vary the frequency of the regulating organ and thus reduce the precision of the watch. A silicon balance spring helps improve these three sources of inaccuracy. Firstly, the silicon balance spring can be thermocompensated, as provided for in document EP 1422436. Secondly, various designs have been proposed to ensure concentric distortion of the balance spring: For example, patent CH 697207 proposes a terminal section that guarantees good isochronism, thus the oscillation period remains unaffected by the amplitude. Lastly, silicon is a non-magnetic material, so the Earth's magnetic field has no influence over the running of the balance spring.

However, manufacturing a silicon balance spring using the photolithography method followed in deep reactive ion etching (DRIE) presents a number of challenges in terms of minimizing the dissipation of the resilient torque of the balance springs on a plate and the variation in resilient torque from one plate to another that are produced at different times.

Firstly, to obtain a multitude of balance springs on a silicon plate, its design is printed on the plate using a photolithography method. This method is based on a mask 10 containing a highly precise drawing of the balance spring. The mask design is printed on a photosensitive resin 24 by exposure to UV light and development in a chemical bath. The person skilled in the art is well aware that exposure and development conditions can change the dimensions of printed structures. Thus, too long an exposure time or too long a development time can reduce the width of the lines of photosensitive resin. There can be an error of up to 0.5 μm from one batch to the next if the parameters are not well controlled.

Secondly, the DRIE method as described in patent U.S. Pat. No. 5,501,893 presents certain challenges arising from the very nature of this etching method: plasma etching is characterized by inconsistent etching speeds depending on the location on the plate. In particular, the etching speed for silicon in the center of a plate is generally slower than towards its rim. This is because plasma is more reactive at the periphery than at the center. Faster etching results in more negative verticality (FIG. 3c) on the rim. Slower etching in the center results in more positive verticality (FIG. 3a or 3d) in the center. This results in dissipation of the resilient torques of the balance springs on a plate, such that their spring constant or their stiffness varies according to their position on the plate. This means that balance springs located on the periphery have a lower resilient torque than the ones in the center.

Various solutions have been devised to solve this problem. A first publication EP3181938B1 proposes photolithography with balance springs of oversized thickness. Accordingly, the balance springs are made too thick. Then, a few balance springs are removed from the plate to measure their resilient torque. This measurement is used to calculate the excess thickness. Carefully targeted oxidation converts this excess thickness into oxide. The oxide is then easily removed without etching the silicon. This method is therefore based on iterative manufacturing, measuring the resilient torque of a few balance springs and reducing the thickness of the remaining balance springs on the plate to the target value. Patent CH 714815 A2 proposes the same method, but the etching mask is made of silicon dioxide rather than photosensitive resin. Moreover, in this method, the balance springs are first etched too thick and then thinned to the desired thickness. The adjustment oxide provides protection while the handle plate is being etched in a potassium hydroxide bath to free the balance spring from the wafer handle. Lastly, document CH 716603 A1 proposes the removal of an excess thickness of silicon dioxide at the end of the process to correct any excess thickness produced. To counteract the effect of dissipation on the plate, the balance springs are designed with wider thicknesses at the rim.

These three methods therefore rely on the manufacture of oversized balance springs. Each plate is individually adjusted by removing the excess thickness. This approach works very well for an initial number of plates. But when batches with a higher number of plates are produced, the method becomes cumbersome: in fact, it means that each plate has to be reworked individually, with a different sub-process adjusted for each plate. Batch production of twenty-five plates is standard practice in the microelectronics field. This kind of batch production, in which all the plates in the batch have the same production parameters, is impossible with the approach used in the prior art. The present invention provides a method that relies on in-process control and its corresponding photolithography mask that enables continuous batch production using statistical process control.

### DESCRIPTION OF THE FIGURES

FIG. 1 shows a simplified top view of a photolithography mask 10 used in the prior art to manufacture horological balance springs 3 with an entire cell 1.

FIG. 2 shows a simplified top view of a photolithography mask 10 for the production of horological balance springs 3 according to the invention.

FIG. 3 shows the various etching profiles that can be produced by adjusting the DRIE parameters. Thickness e1 is the width of the etching mask and e2 is the resulting etching in the silicon. 3a) ideal vertical etching, 3b) under-etching, 3c) negative profile, 3d) positive profile, 3e) profile with a hollow, 3f) elliptical profile

FIG. 4 shows schematic cross-sections of an SOI plate in various steps in its manufacture according to the invention, these steps being:
4a) Photolithography on the device layer of height h covered with silicon dioxide acting as an etching mask.
4b) DRIE of the device layer of the SOI plate forming the balance springs 3 and sacrificial structures 16.
4c) Under-etching the buried oxide to free the measurement actuator.
4d) DRIE of the “handle” layer on the rear face of the SOI plate
4e) Under-etching the buried silicon dioxide to free the balance springs.
4f) Separation of the sacrificial structures 16 from the plate at the end of step 4e).
4g) Oxidation to form the thermocompensation dioxide and cell finished with a balance spring with its thermocompensating oxide, attached to its frame.

FIG. 5 shows the electrostatic measurement actuator used to determine the verticality of the etching.

### DETAILED DESCRIPTION OF THE PREFERRED EMBODIMENTS

FIG. 1 shows a simplified top view of a photolithography mask 10 used in the prior art to manufacture balance springs 3. This mask contains a multitude of similar cells, each of which contains the design of the balance spring to be produced. The part 1 of the mask used to produce a balance spring 3 is therefore referred to as a “cell.” A cell 1 contains a frame 2 with its balance spring 3 and, according to the invention, a new test structure 30 which enables it to be produced with greater precision. The photolithography mask is used to transfer the design, with a high degree of fidelity, onto the silicon plate containing the balance springs. The mask thus contains transparent zones 11 in which the silicon will be etched and opaque zones 12 where the silicon will be kept. The mask thus defines the balance spring 3, with its pinning attachment 5, its coils with variable or constant thickness e and its ferrule 4. The balance spring is attached to the silicon plate by an attachment 6, which can be broken off at a later date to separate the balance spring from the frame of each cell on the plate. For the sake of clarity, only two coils are shown, but the final component can contain many more.

All these embodiments are amply described in the literature and are part of the watchmaker's expertise: silicon allows for considerable freedom of form. The height of the balance spring is not defined by the photolithography mask but by the height h of the device layer 21 of the SOI 20 (Silicon on Insulator) plate. The height h can be measured with good precision and has less influence on the precision of the balance spring. A precision of ±0.5 μm is common for the height h of SOI plates.

The first step in the production of a silicon balance spring according to the prior art therefore begins with the photolithography step shown in FIG. 4a). The thickness e of the balance spring is determined by the width of the photosensitive resin lines. The person skilled in the art knows how to ensure good reproducibility of the thickness e through dimensional control of the developed resin and its transfer to a silicon dioxide etching mask 25, for example by adjusting the exposure time and/or the development time. According to a less advantageous embodiment, the person skilled in the art can directly use the developed photosensitive resin 24 as an etching mask without first transferring it to the silicon dioxide 25. However, a silicon dioxide 25 mask interacts less with the plasma, resulting in greater stability of the DRIE process. In both cases, the person skilled in the art knows how to precisely control the width e and maintain a constant difference with the width designed on the photolithography mask and from one plate to another on the silicon wafer. In fact, there are measuring apparatuses for determining the critical dimension (CD measurement) of photolithography that allow this width to be controlled with a precision that is much more precise than 0.1 μm.

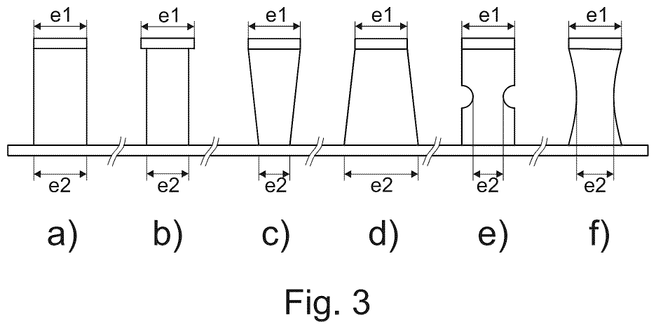

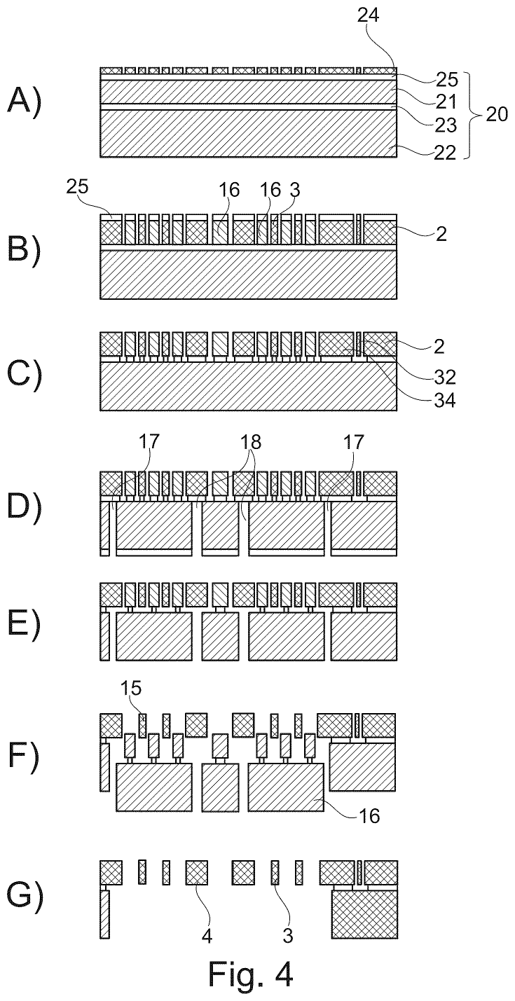

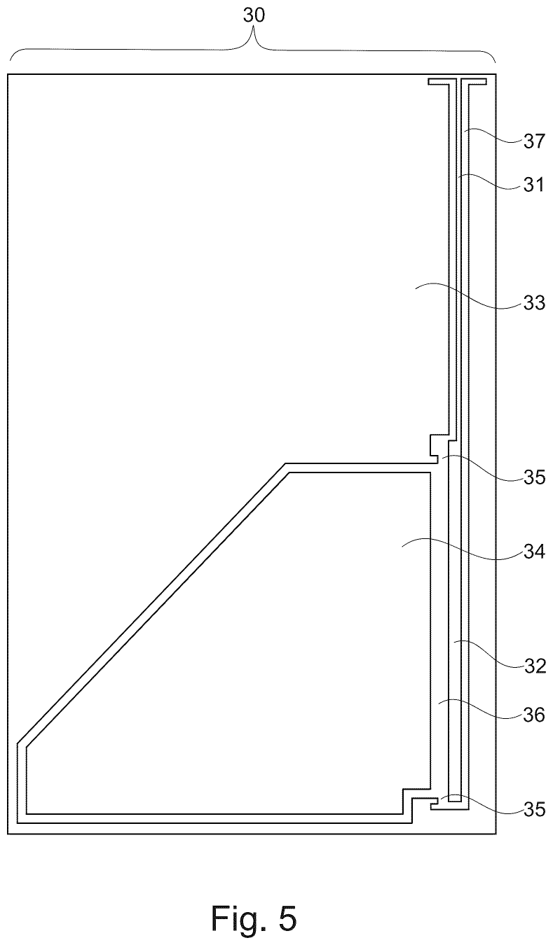

The biggest challenge in making balance springs with good precision lies in the DRIE process. In particular, controlling the verticality of the etching is difficult. FIG. 3 provides an illustration of this problem. In this figure, the width of the coils in the etching mask is referenced e1 and the final thickness of the coils etched into the silicon is referenced e2. Depending on the etching parameters, the initial thickness of the mask e1 can be etched differently into the silicon. The skilled person can adjust the engraving parameters to obtain different profiles in silicon. FIG. 3a) shows an ideal vertical engraving. FIG. 3b) shows under-etching: part of the thickness e1 is lost and the balance spring has a reduced thickness e2 but the thickness is constant over the height. FIG. 3c) shows a negative profile, which means that the coils get thinner as the etching progresses. FIG. 3d) shows a positive profile, in which the etching produces coils that increase in thickness as the etching progresses. The person skilled in the art can also stop the etching in the vertical mode, create a small hollow as shown in FIG. 3e) and then continue with the vertical etching parameters. Lastly, FIG. 3f) shows an elliptical profile. Of course, various simple modifications and variants can be devised by the person skilled in the art without departing from the scope of the invention as defined by the appended claims.

To ensure that there is little dissipation in the resilient torque of the balance springs on a plate, it is important that the thicknesses e1 and e2 (FIG. 3) are identical throughout the plate and from one plate to another, produced at different times. To illustrate the importance of verticality control, a balance spring with a thickness of 20 μm and a height of 120 μm will be used as an example. A verticality error of +0.1° results in an average thickness error of +0.21 μm. A watch running error of 120 seconds per day is referred to as a “class.” Thus a verticality error of +0.1° creates a dissipation of 11 classes at 120 sec. A ±0.1° dissipation in the verticality already results in a dispersion of 22 classes. The aim is to limit dissipation to less than 40 classes on a plate, which means that verticality must be controlled to +0.18°. This means that the number of classes can be kept to under 40 and all the balance springs on a plate can be used. Unfortunately, this level of precision cannot be ensured using the photolithography and DRIE methods in the prior art.

In the DRIE method, the silicon open to the plasma (21) interacts with the etching gases, which are accelerated by the plasma's radio frequency sources. The silicon is transformed by the etching ions into a gaseous compound which is evacuated by vacuum pumps. But these compounds also have an influence on the etching process: they are more concentrated in the center of a plate than at its periphery. As a result, the etching speed is slower at the center than at the rim of the plate. A slower etching speed also results in a more positive verticality (FIG. 3d) at the center and a more negative verticality (FIG. 3c) at the rim.

To better explain this phenomenon, we come back to the case of our balance spring with a 100 μm step and a 20 μm coil thickness: In this case, up to 75% of the silicon is etched and only 25% of the material is kept to form the balance spring 3. In such a case, the silicon surface to be etched exceeds 20% of the plate's total surface area, resulting in substantial etching inconsistency. The variation in the geometric dimensions therefore far exceeds our objective of a precise verticality of ±0.18° between the balance springs on a single plate. In fact, the gaseous compounds produced by etching have a non-negligible concentration relative to the etching gas and interfere with the etching process. These compounds can interact with each other and become more complex. In particular, they can also be redeposited on the plate to be etched or on the walls of the reaction chamber. The electrical capacitance is thus altered by this redeposition, which changes the etching conditions from one plate to the next. This parasitic capacitance then alters the voltage of the ions etching the plate and the verticality deviates from the target value from one plate to the next. This deposit also alters the consistency of the verticality from one plate to the next.

A large surface to be etched results in uneven verticality across a plate and unstable verticality from plate to plate. Verticality control with the required precision becomes impossible. For this reason, masks with excessively large dimensions and thickness adjustment via correction operations are used in the prior art.

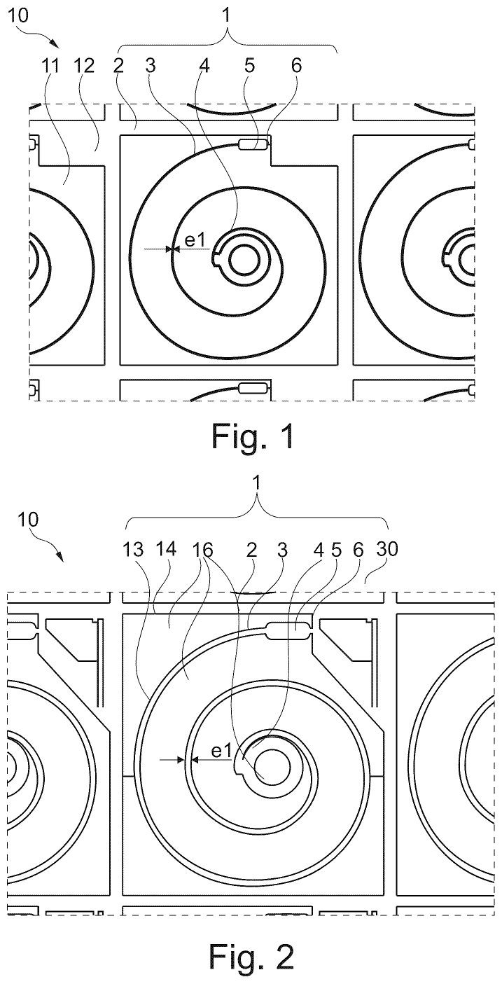

The invention aims to eliminate this adjustment operation. To this end, the surface to be etched 11 is minimized by adding one or more sacrificial structures 16. FIG. 1 shows an etching mask according to the prior art. The white area 11 represents the zone to be etched. The black 12 surface represents the remaining structures after the DRIE process. FIG. 2 shows this mask for the same balance spring according to the invention. The gap between the coils and the gap between the coils and the frame are filled by one or more sacrificial structures 16. The sacrificial structures are separated from the balance spring 3 by one or more continuous contours 13. More advantageously, they are also separated from the frame by one or more contours 14 that run all the way around the frame but leave a thin zone 6 at the attachment 5 to keep the balance spring attached to the frame. The sacrificial structures are attached to the handle plate 22 only by the buried oxide 23. In a less advantageous embodiment, the sacrificial structures 16 are attached to the frame, making it more difficult to separate the balance spring from the plate. Sacrificial structures can be limited to a single contour with a defined width g or the width can be variable: The contour width g can be constant or variable. The contour width g can also remain constant for all balance springs, or, more advantageously, can vary from one balance spring cell to another. We will see below why it is advantageous according to the invention to adjust the contour width from one balance spring to another, depending on the position on the plate. We will also see below how, according to the invention, these sacrificial structures 16 are separated from the plate. With sacrificial structures, the zones to be etched can be reduced, leaving only the contours open to the plasma, so there is very little open surface to be etched. The following numerical values are given as an example. In the case of our exemplary balance spring with 20 μm-thick coils and a 100 μm step, the remaining width 13 to be etched has been reduced from 80 μm to two times 10 μm. Thus, between the coils, the structure 16 has a width of 60 μm and the opening to be etched 13 has a width of 10 μm. The influence of the etching gases on the verticality is thus less affected by silicon-laden etchants. As a result, the plasma etching is limited to the contours 13, and the total surface area to be etched is reduced three to tenfold. As has already been discussed, etchants and etching gases such as octafluorocyclobutane (C₄F₈) and sulfur hexafluoride (SF₆) can form more complex compounds that lead to inconsistent etching and, when redeposited on the walls, make etching non-reproducible from one plate to the next. Thus, according to the invention, sacrificial structures reduce the surface area to be etched and, consequently, there is less interference, less redeposition and therefore better consistency across the plate. Moreover, there is less variation from one plate to the next. Care must be taken to keep an open area of less than 5% of the total surface area of the plate or, less advantageously, an area open to plasma of less than 20% of the total surface area of the plate.

According to the invention, the surface to be etched is suited to the location on the plate. In fact, the verticality of the etching is linked to the etching speed. To obtain the same verticality at the periphery as at the center of the plate, the etching speed at the periphery can advantageously be reduced by decreasing the width of the contour 13. The person skilled in the art is well aware that smaller openings etch more slowly than larger ones. Thus, a smaller contour width is used on the periphery than in the center. As an example, the contours of sacrificial structures can be 8 μm wide at the rim, compared with 16 μm at the center. In an advantageous embodiment of the invention, this etching contour of width g 13 is modified based on the position of the cell on the plate. Advantageously according to the invention, the contour 13 can have a width of 5 μm at the periphery and up to 35 μm in the center. The person skilled in the art will choose values that are intermediate to these exemplary values. The contour 13 width values can and must be varied and adjusted to the geometry to optimize the consistency of the verticality. The person skilled in the art will do so iteratively.

It is important to note that the distribution of the etching speed according to the location on the plate follows a relatively quadratic curve in the radial direction. This means that the etching speed between the periphery and the center does not follow a straight line, but is clearly faster at the rim of the plate and fairly flat at the center. Thus, the etching contour widths are not adjusted in a straight line in the radial direction; instead, widths 13 are chosen to achieve the same verticality at the periphery as at the center, with the structures at the periphery having a smaller width than the ones at the center. According to document CH 716 603 the coil thicknesses are varied to reduce the dissipation of the resilient torques. This approach is less advantageous than varying the etching contour widths, because varying the balance spring thicknesses cannot cancel out the dissipation in the etching and verticality conditions as effectively as varying the contour widths. In fact, the variation in contour widths is virtually unaffected by the etching conditions, which is not the case for the variation in balance spring thicknesses. The method consisting in varying the widths according to the invention is therefore more resistant to process drift.

According to the invention, it has been shown that DRIE consistency and stability can be greatly improved by reducing the surface area to be etched to under 10% and, more advantageously, to under 5% of the total surface area of the plate, by filling the surfaces between the coils and between the coil and the frame with sacrificial structures and by choosing etching widths to suit the location on the plate.

To keep the geometric dimensions of the balance springs identical from one plate to the next, a convenient means of measuring the balance spring geometry is therefore required. According to the invention, this simple means of measuring verticality is provided by the measurement structure 30 shown in FIG. 5. This structure is an electrostatic actuator comprising a deflection blade 31 with a width d advantageously chosen to be smaller than the thickness e of the coils. An actuating electrode 34 is used to move the mobile electrode 32. Advantageously, this mobile electrode 32 is wider than the deflection blade 31 to allow for greater sensitivity in observing its displacement. In a less advantageous embodiment, the mobile electrode 32 is the same width as the blade 31. This entire structure is referred to as an electrostatic actuator 30 and is advantageously positioned next to each balance spring. However, a smaller number of electrostatic measurement actuators—30 per plate—can suffice. The actuator 30 is surrounded by an etching contour 37 which is essentially the same width as the contour 13 described above around the balance spring. The frame outside this contour acts as ground electrode 33. The nature of the DRIE process itself means that this blade 31 has the same verticality as the balance spring, because it is surrounded by a contour 37 of the same width d as the contour 13 around the balance spring.

After the DRIE step, the electrostatic actuator is freed by etching in hydrofluoric acid (HF) in the liquid phase or, more advantageously, in the steam phase. Other structures, such as the balance spring 3 and the sacrificial structures 16, are only partially freed and remain attached to the handle plate. The entire plate is then placed under a microscope, and the electrodes 33 and 34 are connected to a voltage source by needles. Such apparatuses are referred to as “Probers” and are well known to anyone skilled in the art of microelectronics. When voltage is applied by the needles to the electrodes 33 and 34, electrostatic force is exerted on the mobile electrode 32, bending the blade 31. By continuously increasing the voltage, the displacement of the electrode 32 follows a quadratic curve with the voltage. When approximately 30% of the gap 36 between the electrodes 32 and 34 has been covered, the electrostatic actuator becomes unstable and the electrode 32 comes to rest against the stop 35. This characteristic voltage is referred to as “pull-in” or “actuation” voltage by the person skilled in the art. The length and thickness of the blade 31 are chosen so that the pull-in voltage is, for example, 30 V. For example, a blade with a thickness of 5 μm and a length of 1,000 μm will produce a pull-in voltage of 30 V if the gap 36 is carefully selected. As mentioned above, a verticality error of 0.1° causes the equivalent thickness d of the blade to vary by 0.21 μm. This 0.1° change in verticality can be modeled by a change in blade thickness d and the variation in pull-in voltage can be calculated: In the above example, it can be seen that this 0.1° change in verticality results in an increase in the actuation voltage from 30 V to 31.9 V. Therefore, to produce balance springs within a class range of 0 to 40, the actuation voltage should be 30±3.4 V. It should be noted that these values are given as examples and that each balance spring reference will have its own characteristic voltage. In a particularly advantageous embodiment of the invention, the person skilled in the art will choose an automatic method for measuring all the voltages of the actuators distributed over a plate, for example using an automated vision system. This makes it possible to measure the mean, the variation and the change in the distribution of the geometric dimensions of the balance springs on a plate and from one plate to the next.

To keep the manufacturing process within such a narrow vertical range, it is now possible to adjust the DRIE process conditions from one plate to the next when several plates are being manufactured one after the other, thus keeping the actuation voltages constant from one plate to the next. The person skilled in the art knows how to change the verticality by adjusting the time ratio between C₄F₈ deposition and SF₆ etching cycles. This cycle time ratio is an easy way to change the verticality. For example, extending the etching cycle time by 0.1 s/cycle reduces the equivalent thickness of our exemplary balance spring by typically 0.1 μm. The person skilled in the art can therefore easily vary the verticality, according to the invention, synchronously across the entire plate, using the etching contours 13, which have etching widths adjusted to suit the position on the plate. For a more precise adjustment of the verticality, the person skilled in the art will choose to change the plasma power and/or the gas flow. The person skilled in the art will preferably choose the vertical profile shown in FIG. 3a) and will try to vary the parameters to keep the etch profile between FIG. 3c) and FIG. 3d). According to the invention, the most advantageous embodiment is etching with a near-vertical angle located between +0.1° and −0.5°. This offers the best consistency across the plate. In a less advantageous embodiment, the mean angle can be from +0.5° to −1.5°.

The method according to the invention therefore consists in measuring the pull-in voltage of at least one actuator on each plate. If a deviation is measured, the person skilled in the art has to adjust the etching conditions for the next plate so that the target value of the actuator voltages is kept within tolerance. When the target actuation voltage is reached for the actuators, the geometric dimensions of the balance springs are also within the desired tolerance, given the known relationship between the value of the actuation voltage and the value of the resilient torque. At the start of production, a limited number of plates will be scrapped because they are out of tolerance. Mask dimensions such as coil thickness e or contour width g 13 may also need to be adjusted. In this case, the person skilled in the art will change the photolithography mask rather than depart from the ideal etching conditions. Once the statistical process control (“SPC”) method has been set up, the person skilled in the art can produce a large number of plates between the actuator measurement and the adjustment of the etching parameters. Adjustments become predictable. This means that a continuous flow of plates can be produced with no need to rework the individual plates.

To finish manufacturing the balance springs, they still have to be separated from the handle plate. To make the balance springs easier to remove, the portion of the handle plate located under the balance springs has been eliminated. According to the invention, blanked lines 17 (FIG. 4d) are etched into the rear face by DRIE. These lines are continuous under each balance spring cell and their contours are closed under each cell, but the contours are not joined from one cell to the next. A good width for this rear face contour is between 20 and 50 μm. Less advantageously, the width of the blanking contour 17 is thinner, which slows etching down, or wider, which takes up more space under the frame. Etching openings 18 (FIG. 4d) should ideally be placed underneath larger useful structures such as the ferrule. These openings 18 are engraved on the rear face by DRIE at the same time as the contours 17. The openings 18 narrow the gap to be under-etched in hydrofluoric acid. After the DRIE step on the rear face, the plate is immersed in hydrofluoric acid (HF) and the sacrificial structures 16 fall off, as shown in FIG. 4f). Only the handle plate frame remains attached to the device layer frames, or the balance springs remain attached to the frame by their attachment 6 on the stud side.

The final step consists of oxidizing the plate to form the thermocompensating oxide. According to the invention, the plates are positioned such that the plate is placed horizontally in the oxidation furnace with the handle on the lower side, so as to keep the balance spring from shifting off-center during oxidation due to its own weight. According to the invention, the balance springs are not in contact with the carrier, but are held aloft by the plate handle.

To summarize the manufacturing method according to the invention, we refer back to FIG. 4. The method begins with an SOI plate 20 consisting of a device layer 21, a buried silicon dioxide layer 23 and the handle layer 22.

FIG. 4a): the balance springs are photolithographed and their designs are transferred to an etching mask (in photosensitive resin 24 or silicon dioxide 25). The critical widths in this step are measured and the photolithography parameters, respectively the parameters for the transfer to the silicon dioxide, are adjusted to keep these lines with a precision greater than 0.05 μm.

FIG. 4b): the second step consists in etching the silicon with the DRIE process. Here, the etching parameters are controlled so that the geometric shapes of the balance springs fall within the required tolerance.

FIG. 4c): To measure the etching verticality, the electrostatic actuators are freed up in hydrofluoric acid. Depending on the result of this measurement, the etching parameters for the next plates are either kept or adjusted to keep the actuation voltage within a predefined range. The other structures 15, such as the sacrificial structures 16 and balance springs 3, remain attached to the handle plate because the silicon dioxide is only partially etched under these useful structures 15.

FIG. 4d): An etching contour 17 is etched into the rear face by DRIE. This contour has essentially the same form as the contour 14 on the front face, but the rear face contour 17 is closed. In addition, it is moved a little further outwards under the frame so as not to overlap the contour 14, but to stop on the buried dioxide 23. To blank the zones below the balance spring, this contour 17 is placed below the frame. It therefore blanks a zone larger than the front face contour 14.

Structures such as the ferrule 4 or the attachment 5 can be substantially wider than the thickness of the balance spring. To reduce the time required for under-etching in the hydrofluoric acid, it is advantageous to use DRIE to etch hollows under these structures. These hollows are typically recessed by a little more than half the width of the balance spring. For example, if the attachment has a width of 80 μm, an opening in this form will have a width of 50 μm, which is the width of the attachment less a little more than the width of the balance spring.

Once the DRIE has been completed on the rear face, the hydrofluoric acid under-etching can be repeated as shown in FIG. 4e). The zones of the sacrificial structures that have remained attached to the frame and the useful structures 15 by the buried silicon dioxide are freed. Without the bond provided by this oxide, the sacrificial structure falls away as shown in FIG. 4f).

Lastly, as shown in FIG. 4 g), the thermocompensation silicon dioxide is created by thermal oxidation.

Variants of this manufacturing process are possible. It will be particularly advantageous to carry out step d in FIG. 4 at the very beginning of the process so that the hydrofluoric acid step 4c) and 4e) can be carried out at the same time. This is because the actuator is under-etched and the sacrificial structures are freed at the same time. This variant, where step d is carried out before step a, uses the same photolithography masks, but it allows the number of steps to be reduced and the same end result to be obtained.

The following has thus been described:
A method for manufacturing a batch of silicon balance springs from SOI (Silicon On Insulator) plates, designed to keep the value of the resilient torque of the balance springs within a given range with little dissipation within the batch, and
An SOI plate comprising, after a photolithography step and a DRIE step, at least one balance spring structure and a measurement structure, one parameter of which is measurable after said structures have been partially freed by HF etching, the value of said parameter being correlated to the value of the balance spring's resilient torque in a manner known per se.

Of course, the present invention is not limited to the embodiments described above and various simple modifications and variants can be devised by the person skilled in the art without departing from the scope of the invention as defined by the appended claims.

### REFERENCE NUMBERS

1 Cell with balance spring
2 frame
3 coils
4 ferrule
5 pinning attachment
6 frame attachment
10 Mask:
11 zones to be etched
12 zones that remain in silicon
13 etch contour of width g around the balance spring
14 etch contour separating the sacrificial structures from the frame
15 useful structures that remain attached to the plate at the end of the process
16 sacrificial structures that separate after etching the
17 etch contour on rear face separating sacrificial structures from frame
18 etch opening on rear face for freeing large structures
20 SOI plate:
21 device layer on SOI plate
22 handle layer on SOI plate
23 buried silicon dioxide
24 photosensitive resin mask
25 photosensitive resin or silicon dioxide etching mask
30 electrostatic measurement actuator
31 blade with width d
32 mobile electrode joined to the mass electrode by the blade 31
33 mass electrode
34 activation electrode
35 stop
36 distance between the activation electrode 34 and the mobile electrode 32
37 etch contour around the blade 31.
e1 thickness of the coil at the top of the balance spring defined by photolithography
e2 thickness of the coil at the bottom of the balance spring defined by etching
g gap width
h height of the device layer on the SOI plate

1.-9. (canceled)

10. A method for manufacturing a batch of silicon balance springs from SOI (Silicon On Insulator) plates, designed to keep the value of the resilient torque of said balance springs within a given range, comprising, in order, the following steps:
a—Photolithography and deep reactive ion etching (DRIE) of at least one SOI plate, on which there is at least one balance spring structure and a measurement structure,
b—Measuring a parameter of said measurement structure, the value of said measurement parameter being correlated to the value of the resilient torque of the balance spring in a manner known per se,
c—Precision adjusting the photolithography and DRIE parameters based on the value of said measurement parameter, in order to keep the value of the resilient torque of said balance springs within said given range,
d—Iterating steps a, b and c so as to continuously control the dissipation of the resilient torque of the balance springs.

11. The method for manufacturing a batch of silicon balance springs according to claim 10, wherein said measurement structure is an electrostatic actuator, and in that said measurement parameter is its actuation voltage, the value of said voltage being correlated to the value of said resilient torque in a manner known per se.

12. The method for manufacturing a batch of silicon balance springs according to claim 11, wherein said electrostatic actuator comprises a blade with a width d smaller than the thickness el of the balance spring, so as to enhance the photolithographic and DRIE effects on the value of said actuation voltage.

13. The method for manufacturing a batch of silicon balance springs according to claim 12, wherein said blade with width d is completely freed by an HF etching step, leaving the other structures at least partially attached to said SOI plate.

14. The method for manufacturing a batch of silicon balance springs according to claim 10, wherein said DRIE consists of alternating deposit and etching cycles, and in that the main etch setting parameter is the time ratio of said cycles.

15. The method for manufacturing a batch of silicon balance springs according to claim 14, wherein the other important etch setting parameters are gas flow and plasma power.

16. The method for manufacturing a batch of silicon balance springs according to claim 10, wherein said measurement structure is the balance spring itself and in that the measurement parameter is the resilient torque.

17. The batch of balance springs manufactured using the manufacturing method according to claim 10, whereby the value of the resilient torque of said balance springs is kept within a given range with little dissipation.

18. An SOI plate comprising, after a photolithography step and a DRIE step, at least one balance spring structure and a measurement structure, one parameter of which is measurable after said structures have been partially freed by HF etching, the value of said parameter being correlated to the value of the balance spring's resilient torque in a manner known per se.
